(19) United States
(12) Patent Application Publication
(10) Pub. No.: US 2020/0028534 A1
(43) Pub. Date: Jan. 23, 2020

(54) RADIO RECEIVERS

(71) Applicant: Nordic Semiconductor ASA, Trondheim (NO)

(72) Inventor: Pete Sivonen, Trondheim (NO)

(73) Assignee: Nordic Semiconductor ASA, Trondheim (NO)

(21) Appl. No.: 16/480,172

(22) PCT Filed: Jan. 26, 2018
(86) PCT No.: PCT/GB2018/050237

§ 371 Date: Jul. 23, 2019

(30) Foreign Application Priority Data
Jan. 27, 2017 (GB) 1701391.3

(51) Int. Cl. H04B 1/16; H03D 7/14; H03D 7/16

(52) U.S. Cl. CPC H04B 1/16; H03D 7/1441; H03D 2200/0082; H03D 7/1466; H03D 7/165; H03D 7/1458

(57) ABSTRACT

A radio receiver device is arranged to receive an input voltage signal at an input frequency and comprises: a first amplification circuit portion; a second amplification circuit portion; a current buffer circuit portion; and a down-mixer circuit portion. The first amplification circuit portion is arranged to amplify the input voltage signal to generate an amplified current signal which is input to the current buffer circuit portion. The current buffer circuit portion has an input impedance and an output impedance, wherein the output impedance is greater than the input impedance and is arranged to generate a buffered current signal. The down-mixer circuit portion is arranged to receive the buffered current signal and generate a down-converted current signal at a baseband frequency. The second amplification circuit portion is arranged to amplify the down-converted current signal to produce an output voltage signal.

The present invention relates to radio receiver devices, particularly zero-intermediate frequency radio receiver devices.

Radio frequency (RF) receivers are found in a great many electronic devices, for example in modern wireless communication devices such as cellular telephones. Such RF receivers are typically highly integrated, having most of the various transceiver circuits integrated on a radio frequency integrated circuit (RFC). Typically, such radio receivers are implemented using what is known as a “zero-intermediate frequency” (IF) architecture. A zero-IF architecture, produced using a high level of integration, forgoes translating a received signal to an intermediate frequency before further translating it to baseband as with other conventional radio receiver architectures, instead translating the input signal to baseband in one step using single a down-conversion mixer. Zero-IF architectures are particularly favoured for their low bills-of-material (BOM), low cost and particularly low power consumption associated therewith.

Modern radio receivers are implemented using Complementary Metal Oxide Semiconductor (CMOS) technology. CMOS technology has become the most dominant technology for RFIC integration, primarily due to its low cost. For CMOS radio receivers, the current-mode passive mixer topology has become the most popular architecture for implementing the down-conversion mixer. Such a topology typically comprises a low noise amplifier (LNA), a down-conversion mixer, and transimpedance amplifier (TIA) stages. With relatively low supply voltages, the current-mode passive mixer is able to achieve both high linearity and low noise performance simultaneously. Furthermore, since the mixer switches are biased at zero DC-current, they ideally do not generate any low-frequency flicker noise. This is of the utmost importance in a zero-IF receiver, in which the down-converted signal are at DC (i.e. baseband).

In conventional integrated zero-IF radio receivers, the noise performance of the complete integrated receiver is usually limited by the LNA and TIA stages. In practice, the passive current-mode mixer contributes only a little of the total noise. With proper gain partitioning, the noise due to the circuits following the TIA (e.g. any additional filtering stages and/or analogue-to-digital converters) can be suppressed,

Typically the current-mode mixer switches need as large a source impedance driving them as possible in order to reduce noise due to the TIA and to increase linearity. LNAs realised as transconductance amplifiers typically exhibit relatively large output impedances, however various design constraints set limits on how high the output impedance of the LNA can be. In practice, the output impedance of the LNA is not an independent design parameter and its value cannot be optimised or increased independently. As a result, the Applicant has appreciated that there is room for improvement with regard to increasing the driving impedance for switches in a passive current-mode mixer.

Some conventional receivers known in the art per se introduce an RF transconductance amplifier (i.e. a voltage-to-current converter) between the LNA and mixer switches. However, this typically results in significantly lower overall receiver linearity, for example in terms of input-referred compression point (ICP) and third-order intercept point (IIP3), than would be the case if the mixer were driven directly by the LNA as the transconductance amplifier typically dominates the IIP3 and ICP. For example, if the mixer is provided with a transconductance amplifier with its associated third-order intercept point IIP³_{MIX} (typically measured in terms of input signal power (dBm) dissipated in a reference 100Ω resistor), the complete receiver IIP3 is by an LNA voltage gain lower than it would be without the contribution of the transconductance amplifier to the total IIP3. For example, with IIP3_{MIX}=+10 dBm and a voltage gain A_{V,LNA}=20 dB, the complete receiver displays an IIP3 of −10 dBm (neglecting any contributions to the IIP3 from the LNA or any other receiver circuitry).

When viewed from a first aspect, the present invention provides a radio receiver device arranged to receive an input voltage signal at an input frequency, the radio receiver device comprising:
a first amplification circuit portion arranged to amplify the input voltage signal to generate an amplified current signal;
a current buffer circuit portion arranged to receive the amplified current signal and generate a buffered current signal, said current buffer circuit portion having an input impedance and an output impedance, wherein said output impedance is greater than said input impedance;
a down-mixer circuit portion arranged to receive the buffered current signal and generate a down-converted current signal at a baseband frequency; and
a second amplification circuit portion arranged to amplify the down-converted current signal to produce an output voltage signal.

In at least its preferred embodiments, the present invention provides an improved radio receiver device that reduces the amount of noise introduced by the second amplification circuit portion. Due to the current buffer circuit portion (the output impedance of which is typically much greater than its input impedance), the first amplification circuit portion “sees” a lower impedance “looking” downstream into the down-mixer circuit portion. Conversely, the second amplification circuit portion sees a higher impedance looking upstream into the down-mixer circuit portion (which provides a larger driving impedance for the mixer switches). Thus it will be appreciated by those skilled in the art that a radio receiver device in accordance with the present invention may also exhibit improved DC-offset performance when compared with conventional zero-IF radio receiver devices. Inserting an RF current-mode buffer between first amplification circuit portion and the down-mixer circuit portion may result in only slightly degraded receiver linearity in terms of ICP and IIP3. Namely, assuming the LNA driving the RF current-mode buffer has relatively large output impedance, the RF current-mode buffer generates only a small amount of non-linearity. With regard to the receiver's second-order intercept point (IIP2), a measure of linearity that quantifies the second-order distortion generated by nonlinear systems and devices which is usually limited by the mixer switches, a radio receiver device in accordance with embodiments of the present invention may exhibit an improved IIP2. It will be understood by those skilled in the art that a down-mixer circuit as described herein is a down-conversion mixer circuit.

While it will be appreciated by those skilled in the art that the present invention can be readily applied to any amplifier that provides a sufficiently large output impedance compared to the input impedance of the current buffer circuit portion, in at least some preferred embodiments the first amplification circuit portion comprises a low noise amplifier. The low noise amplifier is preferably an RF transconductance amplifier. This allows a high enough output impedance. Thus ideally all RF output current is driven to the low input impedance of the RF current buffer circuit portion and not to the parasitic impedances presented at the output of the low noise amplifier.

Similarly, in at least some preferred embodiments the second amplification circuit portion comprises a transimpedance amplifier.

In preferred embodiments the current buffer circuit portion has a low input impedance and a high output impedance. It will be appreciated that typically, a low input or output impedance is ideally zero while a high input or output impedance is ideally infinite. Of course, in reality the actual values that qualify as a “low” or a “high” impedance are determined by what is deemed tolerable by the designer. For example, a low impedance at RF frequencies may be any impedance less than 100Ω, preferably less than 50Ω, and more preferably less than 10Ω. Similarly, a high impedance at baseband frequencies may be any impedance greater than 1 kΩ, preferably greater than 10 kΩ, and more preferably greater than 100 ckΩ. The ratio between the high input or output impedance and the corresponding low output or input impedance of a given amplifier is preferably greater than ten, more preferably greater than a hundred, yet more preferably greater than a thousand. As the current buffer is located between the first amplification circuit portion and the down-mixer circuit portion, it will be appreciated that the current buffer operates at the input frequency (i.e. at RF frequencies).

The radio receiver device of the present invention could, at least in some embodiments, be implemented using single-ended current buffer and a single-balanced mixer circuit. However, in other embodiments, the down-mixer circuit portion comprises a double balanced mixer circuit and the current buffer comprises a balanced current buffer. In such embodiments, the input signal, amplified signal, buffered signal, and output signal are differential. In preferred embodiments, the output signal comprises an in-phase output signal and a quadrature output signal.

While it will be appreciated that a radio receiver device in accordance with embodiments of the present invention can be implemented using a number of current buffer circuit topologies known in the art per se, in some preferred embodiments the current buffer circuit portion comprises a cross-coupled common-gate circuit. As will be understood by those skilled in the art, cross-coupled common-gate (or “CG”) technology uses a pair of complementary metal-oxide-semiconductor (CMOS) field-effect-transistors (FETs) to transfer current from its input to its output. In some such embodiments, the cross-coupled common gate circuit comprises first and second p-channel (or “pMOS”) FETs, arranged such that: the gate terminal of each of said first and second p-channel FETs is connected to the source terminal of the other one of said first and second p-channel FETs via first and second AC coupling capacitors respectively; the respective source terminals of said first and second p-channel FETS are connected to the amplified signal; and the drain terminals of said first and second p-channel FETs are connected to ground via first and second n-channel (or “nMOS”) FETs, wherein the drain terminal of the first n-channel FET is connected to the drain terminal of the first p-channel FET; the drain terminal of the second n-channel FET is connected to the drain terminal of the second p-channel FET; the source terminals of said first and second n-channel FETs are connected to ground; and the gate terminals of said first and second n-channel FETs are connected to first and second bias voltages respectively. In preferred embodiments, said first and second bias voltages are the same. The AC coupling capacitors act to prevent DC signals (e.g. the supply voltage) from being applied to the gate terminals of the gate terminals of the first and second p-channel FETs. The buffered current signal is taken from the drain terminals of the n and p-channel FETs.

It will be understood from the above description that embodiments of the present invention provide an RF current-mode buffer—i.e. an active buffer between the LNA and mixer stages. This provides certain benefits over alternative implementations, such as passive impedance networks. It will be understood by those skilled in the art for example, that an active buffer would comprise transistors such as FETs which are actively powered, i.e. with a drain-to-source voltage of greater than zero, and can thus achieve a larger output impedance than what is achievable with a passive network (depending on frequency).

The implementation described herein provides high mixer output impedance, resulting in overall reduced noise, together with reduced DC offset. These advantages provide improvements over the prior art. Whilst this may be at the cost of increased DC power consumption and reduced linearity, the applicant has realised that this may be an acceptable trade-off, as it may provides acceptable losses for practical implementations.

Certain embodiments of the present invention will now be described with reference to the accompanying drawings, in which:

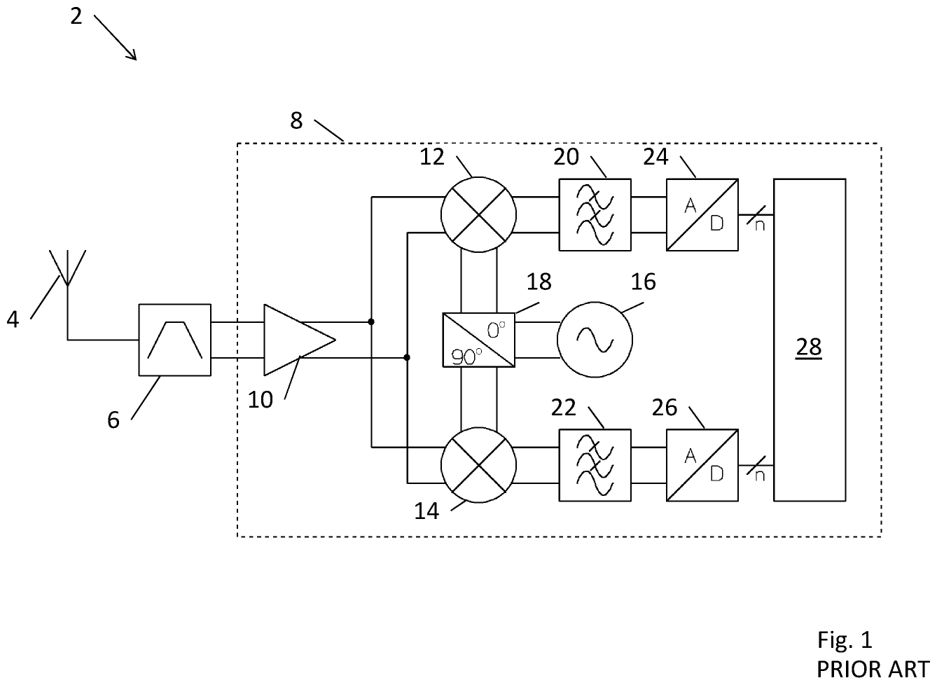

FIG. 1 is a block diagram of a conventional zero-IF radio receiver architecture;

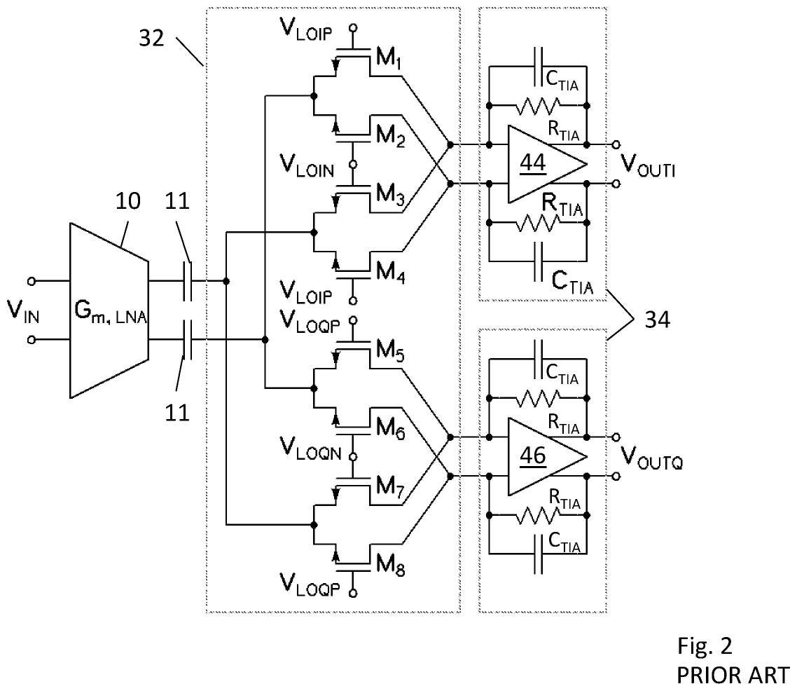

FIG. 2 is a schematic diagram of a conventional current-mode passive mixer that may be used in the receiver of FIG. 1;

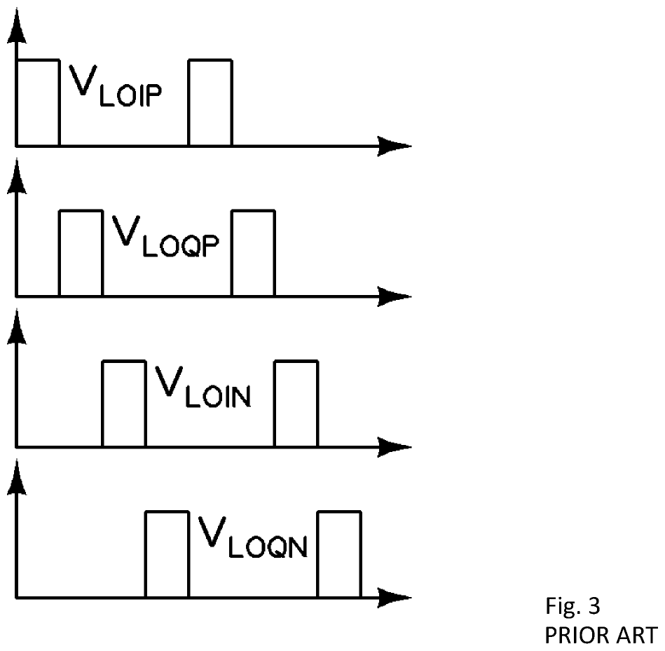

FIG. 3 illustrates quadrature non-overlapping local oscillator signals typically applied to the mixer of FIG. 2;

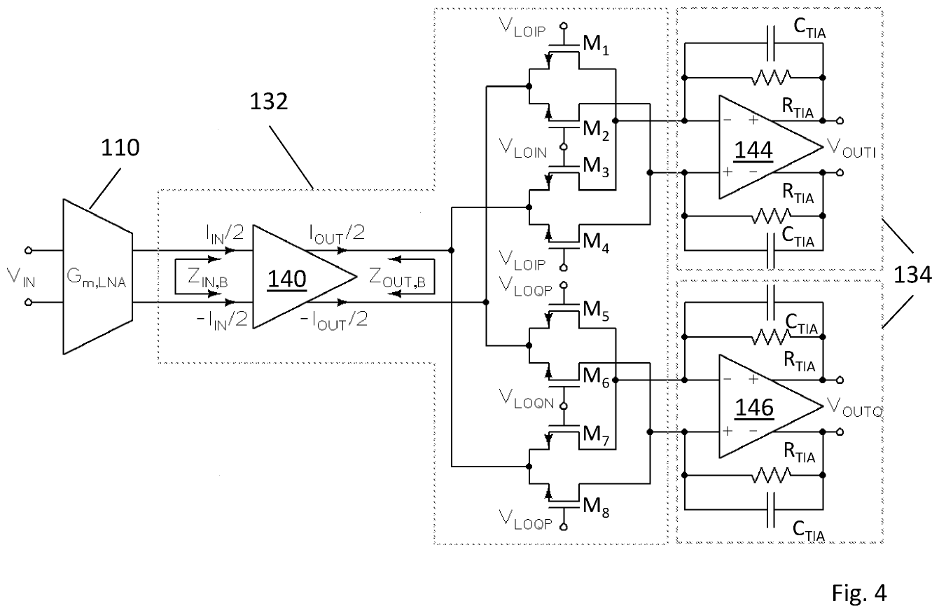

FIG. 4 is a circuit diagram of current-mode passive mixer with an RF current-mode buffer in accordance with an embodiment of the present invention;

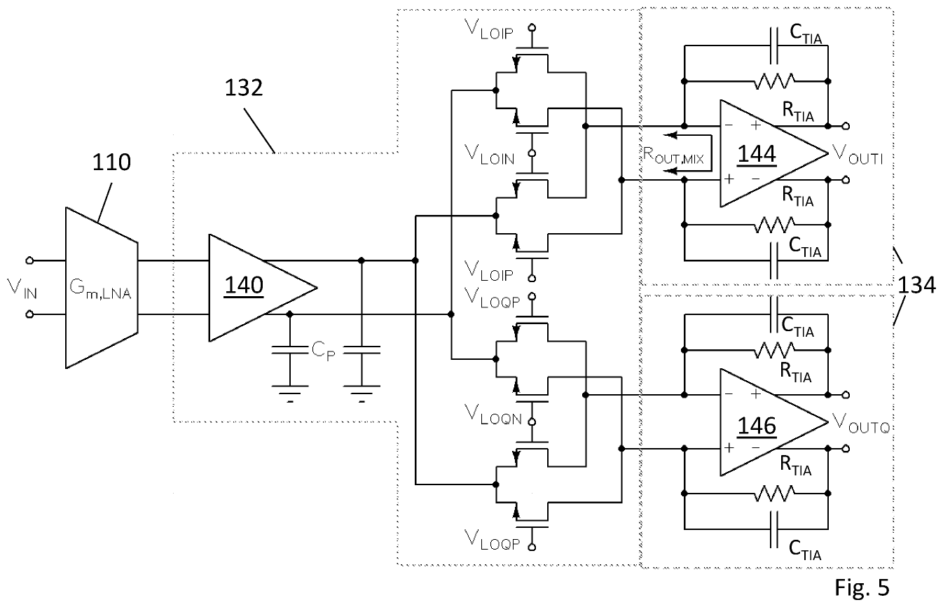

FIG. 5 is a circuit diagram of a switched capacitor network equivalent circuit for evaluating the output resistance of the mixer of FIG. 4;

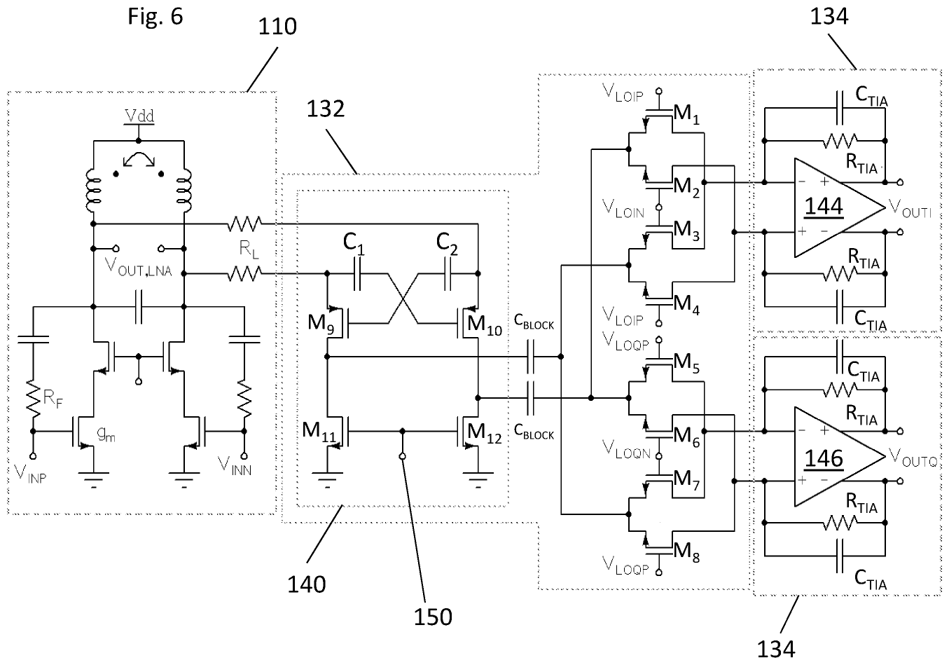

FIG. 6 is a circuit diagram of an RF front-end with a cross-coupled pMOS common-gate circuit implementation of the RF current-mode buffer of FIG. 4; and

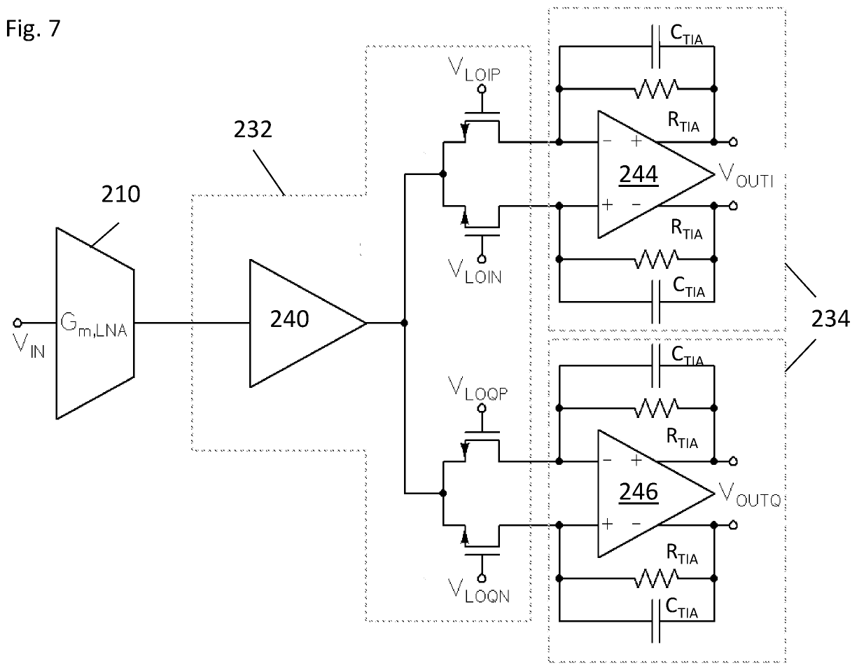

FIG. 7 is a circuit diagram of a single-balanced current-mode passive mixer with a single-ended RF current-mode buffer in accordance with a further embodiment of the present invention.

FIG. 1 is a block diagram of a conventional, fully balanced zero-IF radio receiver architecture 2. The radio receiver 2 comprises an antenna 4; an RF bandpass filter 6; and an radio frequency integrated circuit (RFIC) 8. The RFIC 8 comprises: a low noise amplifier (LNA) 10; two mixers 12, 14; a local oscillator 16; a quadrature phase shifter 18; two low pass filters 20, 22; two analogue-to-digital converters 24, 26; and digital circuitry 28. It will of course be appreciated that the RFIC 8 may comprise other components (e.g. an RF transmitter), however these are not shown here for ease of illustration.

The antenna 4 picks up RF signals, which are passed through the bandpass filter 6, which provides the incoming balanced signal to the LNA 10. The LNA 10 amplifies the incoming signal and provides the amplified signal to the two mixers 12, 14. A local oscillator 16 generates a local oscillator signal that is used by the phase shifter 18 to generate an in-phase (I) local oscillator signal and a quadrature (Q) local oscillator signal. An in-phase mixer 12 mixes the amplified signal with the in-phase local oscillator signal to generate an in-phase baseband signal. Similarly, a quadrature mixer 14 mixes the amplified signal with the quadrature local oscillator signal to generate a quadrature baseband signal. The respective in-phase and quadrature baseband signals are then filtered by low-pass filters 20, 22 to remove upper sidebands and to attenuate any unwanted signals. The resulting filtered signals are converted to digital signals by ADCs 24, 26 and input to the further digital circuitry 28 which may perform any digital signal processing (DSP) steps required by any particular demodulation scheme in use.

FIG. 2 is a schematic diagram of a conventional current-mode passive mixer that may be used in the radio receiver 2 of FIG. 1. FIG. 2 shows the RF “front-end”, which includes the LNA 10, I/Q down-conversion mixer circuitry 32, and trans-impedance amplifiers (TIA) 34. Here, the LNA 10 is realized as a transconductance amplifier having transconductance of G_{m,LNA}. As a transconductance amplifier, the LNA 10 amplifies the input RF voltage and converts it to an RF output current suitable for driving in-phase (I) and quadrature-phase (Q) mixer switches as will be discussed below. Transconductance amplifiers are most commonly used in zero-IF RF front-end architectures for driving the current-mode I/Q-down-conversion mixer.

In general, the LNA 10 should provide a stable termination impedance (typically 50Ω or 100Ω for a balanced LNA) for the RF filter 6 preceding the LNA 10. In addition, the LNA 10 should have a low noise figure (NF) and sufficiently high linearity. Furthermore, when driving the current-mode mixer, the LNA 10 should possess a sufficiently large output impedance or equivalent RF source impedance for the current-mode mixer for reasons discussed below.

The traditional current-mode passive (double-balanced) IQ-mixer illustrated in FIG. 2 consists of eight FET switches (M₁-M₈), which are driven by the I- and Q-local oscillator (LO) signals generated by the local oscillator 16 and phase shifter 18 as described previously with reference to FIG. 1. The uppermost four FET switches M₁-M₄ form the in-phase mixer 12 described previously with reference to FIG. 1 while the lowermost four FET switches M₅-M₈ form the quadrature mixer 14. The Q-LO signal is 90° out of phase with the I-LO signal. It is customary to use non-overlapping 25% duty cycle LO signals for driving the passive mixer, as shown in FIG. 3. As a result, only a single-pair of mixer switches is conducting at time. For example, when V_{LOIP} is high, only M₁ and M₄ are conducting.

The current-mode passive mixer is loaded by the TIA 34 at baseband, or in general, by a transresistance buffer. The TIA 34 converts the down-converted mixer output current to a baseband voltage with first-order low-pass filtering provided by the resistor-capacitor feedback networks (examples of which are labelled “R_{TIA}” and “C_{TIA}”). Often, the TIA 34 is followed by additional low-pass filtering stages (not shown). The TIA 34 provides a virtual ground at its differential input or at mixer baseband outputs. Additional passive capacitance may be applied at the TIA inputs in order to provide low impedance termination for the mixer outputs and for the out-of-band signals and blockers (not shown). Due to the virtual ground at the mixer baseband outputs (and, to a lesser degree, the capacitance at the mixer outputs), unwanted blocking signals cause only a small voltage swing across the mixer switches. As a result, the mixer switches M₁ to M₈ generate relatively little nonlinearity, resulting in good mixer linearity and is one of the primary benefits of current-mode passive mixers for use in radio receivers which require a relatively high degree of linearity.

As the mixer switches M₁ to M₈ are biased at zero DC current, they do not generate any flicker noise, at least in the absence of large blocking currents. DC-blocking capacitors 11 are typically applied at the output of LNA 10 so as to ensure that no DC current flows thorough the switches M₁ to M₈.

As described above, the LNA 10 amplifies the incident RF input voltage (V_{IN}) and converts it to an RF output current. The output current of the LNA 10 is commutated by the current-mode mixer 32 controlled by the non-overlapping quadrature LO signals in order to down-convert the signal to baseband. At the mixer output, the down-converted baseband current is driven to the TIAs 34, where it is low-pass filtered (i,e, by the active filters implemented using operational amplifiers 44, 46) and converted to baseband in-phase and quadrature output voltages V _{OUTI}, V_{OUTQ} respectively. Assuming 25% LO duty cycle, the voltage gain from the input of the LNA 10 to the output of each TIA 34 (I-channel or Q-channel) is given by Equation 1 below:

$${A}_{V} = {G}_{m , LNA} \frac{\sqrt{2}}{π} {R}_{TIA}$$

Equation 1: Voltage gain between the input of the LNA 10 and the output of each TIA 34

where

$$\frac{\sqrt{2}}{π}$$

is the frequency conversion loss and R_{TIA} is the feedback resistance of the TIA.

For optimum receiver noise, DC-offset, and linearity performance, the current-mode passive mixer 32 needs to be driven by a large impedance and loaded by a small impedances. In other words, the impedance seen by the mixer RF-port towards the LNA 10 should be relatively large, while the impedance seen by the mixer towards baseband should be sufficiently low.

In practice, the LNA 10 driving the mixer 32 at RF frequencies needs to have large output impedance and the TIAs 34 should present a low-impedance load for the mixer 32 at baseband. Low impedance loads at baseband frequencies can be implemented in relatively straightforward manner, e.g. implementing the TIAs 34 with an operational amplifier in the negative feedback configuration. However, the implementation of high driving impedances (i.e. the output impedance of the LNA 10) at RF frequencies is much more challenging. Unfortunately, if the driving impedance for the current-mode passive mixer 32 is too low, it may result in a penalty in receiver performance in terms of noise, DC-offset, and linearity.

FIG. 4 is a circuit diagram of current-mode passive mixer with an RF current-mode buffer in accordance with an embodiment of the present invention. As described in detail below, the circuit of FIG. 4 implements an increased driving impedance for the current-mode passive mixer, resulting in improvements in both the receiver noise, linearity and DC-offset performance compared to existing solutions to the problem described with reference to FIGS. 1 and 2.

As described previously, it is important that the LNA 110 (again implemented as a transconductance amplifier) sees a low impedance towards the mixer 132 in a zero-IF radio receiver. This guarantees that the maximum amount of RF output current produced by the LNA 110 is driven to the mixer 132 instead of to the parasitic impedances presented at the output of the LNA 110. It is also important that the TIAs 134 see a high impedance looking into the mixer. Both of these requirements are fulfilled by introducing an RF current-mode buffer 140 between the output of the LNA 110 and mixer switches M₁ to M₈. In this particular example, the RF current-mode buffer 140 is considered to be part of the current-mode passive mixer 132, however this is not necessary and they may be implemented either separately or commonly as appropriate.

Since the current-mode buffer 140 operates between the output of the LNA 110 and the mixer switches M₁ to M₈, it necessarily operates at RF frequencies. Ideally, the RF current-mode buffer 140 has low input impedance Z_{IN,B} and large output impedance Z_{OUT,B}, which is customary for current-mode buffers. Although not shown explicitly in FIG. 4, DC-blocking capacitors may or may not be needed at the buffer input or output, similarly to the capacitors 11 described previously with reference to FIG. 2.

As discussed earlier, the LNA 110 realised as a transconductance amplifier converts the input RF voltage (V_{IN}) to the RF output current via conversion gain G_{m,LNA} in accordance with Equation 2 below.

I_{OUT,LNA}=G_{m,LNA}V_{IN}

Equation 2: Relationship between input voltage and output current for the LNA 110

The output current is fed from the LNA 110 to the RF current-mode buffer 140 and ideally I_{IN}=I_{OUT,LNA}. In addition, the RF current-mode buffer ideally conveys or buffers the LNA output current to the buffer output, i.e. I_{OUT}=I_{IN}=I_{OUT,LNA}. In reality however, some losses exist in the buffer and thus the buffer output current may be lower than its input RF current. In some case, there may be also current amplification in the buffer 140 and in that case, I_{OUT}>I_{IN}=I_{OUT,LNA}.

The purpose of the RF current-mode buffer 140 is to provide large impedance Z_{OUT,B} which is seen by the mixer switches M₁ to M₈ when looking into the buffer 140, i.e. large equivalent driving impedance for the mixer switches M₁ to M₈. As a result the output impedance of the mixer 132 can be maximised and the noise and DC-offset due to the op-amps within the TIAs 134 experience low amplification from the TIA input to the TIA output. Furthermore, due to the large buffer output impedance Z_{CUT.B}, the mixer switches M₁ to M₈ may generate lower second order distortion and higher IIP2 may be achieved when compared to conventional solutions. Accordingly, improved receiver performance in terms of noise, DC-offset, and IIP2 is achieved.

It may be seen in summary that the LNA 110 converts the input voltage V_{IN} to an output current by voltage-to-current amplification. The RF current buffer 140 then buffers the current I_{IN} output from the LNA 110. The rest of the mixer 132 performs frequency translation (with conversion loss) from RF to baseband to produce output currents. The mixer 132 therefore has its inputs and outputs as currents. Finally the TIAs 134 convert the mixer output baseband currents to baseband voltages V_{OUTI} and V_{OUTQ}.

In practice, the achievable maximum buffer and mixer output impedances depend on the design details of the RF current-mode buffer 140. FIG. 5 shows a circuit diagram of a switched capacitor network equivalent circuit for evaluating the output resistance of the mixer of FIG. 4. As will be explained below, even with good design the parasitic capacitance C_{P} at the output of the buffer 140 limits the achievable buffer output impedance and mixer output resistance at the given RF operation frequency f₀.

Due to the switched-capacitor effect, the parasitic capacitance C_{P} at the output of the RF current-mode buffer 140 limits the output resistance R_{OUT,MIX} of the mixer 132 in accordance with Equation 3 below:

$$Output resistance of the mixer 132 \\ {R}_{OUT , MIX} = 2 ( {R}_{OUT , LNA} + 2 {R}_{SW} ) = 2 ( \frac{1}{4 {f}_{LO} {C}_{P}} + 2 {R}_{SW} ) \qquad Equation 3$$

where f_{LO} is the LO frequency or RF operation frequency. Thus in order to maximize the mixer output resistance, the parasitic capacitance C_{P} at the output of the RF current-mode buffer 140 is ideally minimised.

FIG. 6 is a circuit diagram of an RF front-end with a cross-coupled pMOS common-gate circuit implementation of the RF current-mode buffer 140 of FIG. 4. In practice, the RF current-mode buffer 140 may be implemented using one of many well-known techniques known in the art per se.

The cross-coupled common-gate buffer 140 is implemented using a pair of pMOSFETs M₉, M₁₀ arranged such that the gate terminal of each of the first and second pMOSFETs M₉, M₁₀ is connected to the source terminal of the other via an AC-coupling capacitors C₁, C₂. The respective source terminals of the two pMOSFETs are connected to the output of the LNA 110. Furthermore, the drain terminals of the two pMOSFETs M₉, M₁₀ are connected to the respective drain terminals of two nMOSFETs M₁₁, M₁₂ which operate as current sources to bias the two pMOSFETS M₉, M₁₀ (i.e. the drain terminal of one nMOSFET M₁₁ is connected to the drain terminal of one pMOSFET M₉ while the drain terminal of the other nMOSFET M₁₂ is connected to the drain terminal of the other pMOSFET M₁₀). The source terminals of the two nMOSFETs M₁₁, M₁₂ are connected to ground and their respective gate terminals are connected to a bias voltage via a bias input 150. The buffered current signal is taken from the drain terminals of M₉-M₁₂.

Here, the LNA 110 is implemented as a “resistive feedback” LNA (or “RFB-LNA”). The LNA load resistance R_{L} is here connected in series with the input of the RF current-mode buffer 140. In this case, the differential input impedance of the buffer 140 is given by Equation 4 below:

$$Differential input impedance of the buffer 140 \\ {Z}_{IN , B} = \frac{1}{{g}_{m , B}} \qquad Equation 4$$

wherein g_{m,B} the transconductance of the buffer input pMOSFET M₁₀ (or equivalently the transconductance of the buffer input pMOSFET M₁₁ as they are typically equal to one another).

In addition, the LNA 110 sees an equivalent differential load resistance, which is given as per Equation 5.

$$Equivalent differential load resistance \\ as seen by LNA 110 \\ {R}_{L , EQ} = 2 {R}_{L} + {Z}_{IN , B} = 2 {R}_{L} + \frac{1}{{g}_{m , B}} \qquad Equation 5$$

The output of the LNA 110 is presented as a voltage which is converted to an RF current via a load resistor R_{L,EQ}. This current is buffered by the RF current-mode buffer 140 and driven as a current to the mixer switches M₁ to M₈. The output impedance of the current-mode buffer 140 and the mixer output resistance are both limited by the parasitic capacitance at the buffer output, as discussed above. In this example, DC-blocking capacitors C_{BLOCK} are applied at the output of the buffer 140 so as to guarantee no DC-current flows through the mixer switches M₁ to M₈.

In the embodiment described above, the current-mode passive mixer with RF current-mode buffer is realized with differential RF buffer input and double-balanced IQ-mixer, i.e. all mixer ports (RF, LO, and baseband) are differential. By way of contrast, FIG. 7 is a circuit diagram of a single-balanced current-mode passive mixer with a single-ended RF current-mode buffer in accordance with a further embodiment of the present invention. In this case, a single-ended LNA 210 is followed by a single-balanced passive current-mode IQ-mixer 232 with a single-ended RF current-mode buffer 240.

Thus it will be seen that the present invention provides a radio receiver device that implements a current buffer between the initial amplification stage and the down-mixing stage, resulting in improved noise and linearity characteristics. It will be appreciated by those skilled in the art that the embodiments described above are merely exemplary and are not limiting on the scope of the invention.

1. A radio receiver device arranged to receive an input voltage signal at an input frequency, the radio receiver device comprising:
a first amplification circuit portion arranged to amplify the input voltage signal to generate an amplified current signal;
a current buffer circuit portion arranged to receive the amplified current signal and generate a buffered current signal, said current buffer circuit portion having an input impedance and an output impedance, wherein said output impedance is greater than said input impedance;
a down-mixer circuit portion arranged to receive the buffered current signal and generate a down-converted current signal at a baseband frequency; and
a second amplification circuit portion arranged to amplify the down-converted current signal to produce an output voltage signal.

2. The radio receiver device as claimed in claim 1, wherein the first amplification circuit portion comprises a low noise amplifier.

3. The radio receiver device as claimed in claim 1, wherein the second amplification circuit portion comprises a transimpedance amplifier.

4. The radio receiver device as claimed in claim 1, wherein the current buffer circuit portion has a low input impedance and a high output impedance.

5. The radio receiver device as claimed in claim 1, wherein the down-mixer circuit portion comprises a double balanced mixer circuit and the current buffer comprises a balanced current buffer.

6. The radio receiver device as claimed in claim 5, wherein the output signal comprises an in-phase output signal and a quadrature output signal.

7. The radio receiver device as claimed in claim 1, wherein the current buffer circuit portion comprises a cross-coupled common-gate circuit.

8. The radio receiver device as claimed in claim 7, wherein the cross-coupled common gate circuit comprises first and second p-channel field-effect-transistors, arranged such that:
the gate terminal of each of said first and second p-channel field-effect-transistors is connected to the source terminal of the other of said first and second p-channel field-effect-transistors via first and second AC coupling capacitors respectively;
the respective source terminals of said first and second p-channel field-effect-transistors are connected to the amplified signal; and
the drain terminals of said first and second p-channel field-effect-transistors are connected to ground via first and second n-channel field-effect-transistors,
wherein the drain terminal of the first n-channel field-effect-transistor is connected to the drain terminal of the first p-channel field-effect-transistor; the drain terminal of the second n-channel field-effect-transistor is connected to the drain terminal of the second p-channel field-effect-transistor; the source terminals of said first and second n-channel field-effect-transistors are connected to ground; and the gate terminals of said first and second n-channel field-effect-transistors are connected to first and second bias voltages respectively.

9. The radio receiver device as claimed in claim 8, wherein said first and second bias voltages are the same.

10. The radio receiver device as claimed in claim 1 wherein the current buffer circuit portion comprises an active buffer.

11. The radio receiver device as claimed in claim 1 wherein the current buffer circuit portion is a RF current mode buffer.
